(19) United States
(12) Patent Application Publication
(10) Pub. No.: US 2006/0269690 A1
(43) Pub. Date: Nov. 30, 2006

(54) Formation technology for nanoparticle films having low dielectric constant

(75) Inventors: Yukio Watanabe, Higashi-ku (JP); Masaharu Shiratani, Higashi-ku (JP); Kazunori Koga, Higashi-ku (JP); Shota Nunomura, Higashi-ku (JP); Shingo Ikeda, Tokyo (JP); Nobuo Matsuki, Tokyo (JP); Atsuki Fukazawa, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignees: ASM JAPAN K.K., Tokyo (JP); Kyushu University, National University Corporation, Higashi-ku (JP)

(21) Appl. No.: 11/139,311

(22) Filed: May 27, 2005

(51) Int. Cl. H05H 1/24; C23C 16/00

(52) U.S. Cl. 427/569; 427/248.1

(57) ABSTRACT

A method for forming a low dielectric constant film includes the steps of: introducing reaction gas comprising an organo Si gas and an inert gas into a reactor of a capacitively-coupled CVD apparatus; adjusting a size of fine particles being generated in the vapor phase to a nanometer order size as a function of a plasma discharge period inside the reactor; and depositing fine particles generated on a substrate being placed between upper and lower electrodes inside the reactor while controlling a temperature gradient between the substrate and the upper electrode at about 100° C./cm or less.

### BACKGROUND OF THE INVENTION

1. Field of the Invention

The present invention relates to a technology for forming films having a porous structure and a low dielectric constant (k) by forming nanometer-diameter particles having an insulating SiOCH or SiC composition in the vapor phase, with plasma CVD using silicon-containing gas as a source gas, and depositing these particles on wafers.

2. Description of the Related Art

As the device node is reduced, interlayer insulation films having low dielectric constants (low-k) are desired for devices as shown in the following table:

| Time of Application | Device Node | k |
|---|---|---|
| 2003 | 90 nm | 2.9-3.1 |
| 2005 | 65 nm | 2.6-2.8 |
| 2007 | 45 nm | 2.2-2.4 |

As for low-k films having a dielectric constant of about 2.7, many film formation methods including CVD and coating methods have been proposed, formation of high-quality low-k films has become possible in recent years, and application of the device node 90 nm to mass production devices has been started. For next-generation high-speed devices, low-k films having further low dielectric constants of about 2.5 or below are desired.

As one embodiment of the methods, a method of forming low-k films by forming nanoparticles and depositing them on substrates has been known. For example, in U.S. Pat. No. 6,737,366 and No. 6,602,800, a method in which an intermediate electrode between upper and lower electrodes is provided to divide a reactor into upper and lower spaces so as to suppress plasma generation in a lower space, and to reduce electric charge so as to facilitate nanoparticles to be deposited onto a substrate without being affected by static charge, was disclosed. Additionally, in U.S. Pat. No. 6,537,928, a method, in which by disposing a cooling plate between the intermediate electrode and a susceptor in addition to an intermediate electrode, a temperature of a lower space is controlled at a lower temperature so as to facilitate nanoparticles to be deposited on a substrate utilizing moisture, was disclosed.

### SUMMARY OF THE INVENTION

The present invention is a technology for depositing nanoparticles on a substrate by controlling nanoparticle generation itself. In other words, provided is a technology for forming a low dielectric constant film on a substrate by forming insulating fine particles in the vapor phase, with plasma CVD using silicon-containing gas as a source gas, and efficiently transferring the fine particles formed to a surface of the substrate while suppressing their coagulation.

According to an embodiment, the present invention provides a method for forming low dielectric constant films comprising the steps of: (I) introducing reaction gas comprising an organo Si gas and an inert gas into a capacitively-coupled CVD apparatus; (II) adjusting a size of fine particles (nanoparticles) being generated in the vapor phase to a nanometer order size as a function of a plasma discharge period inside the reactor; and (III) depositing fine particles generated on a substrate being placed between upper and lower electrodes inside the reactor while controlling a temperature gradient between the substrate and the upper electrode at about 100° C./cm or less, including 90° C./cm, 80° C./cm, 70° C./cm, 60° C./cm, 50° C./cm, 40° C./cm, 30° C./cm, 20° C./cm, 10° C./cm, 5° C./cm, 0° C./cm, and ranges between any two numbers of the foregoing (preferably 50° C./cm or less), preferably wherein the temperature of the lower electrode is higher than that of the upper electrode.

In the above, in step (II), the size of nanoparticles may be controlled by the duration of RF discharges, wherein nanoparticles generated (or polymerized) from radicals and the remaining radicals co-exist (the size of radicals may be about 0.5 nm or less, and the size of nanoparticles is normally larger than about 0.5 nm; typically about 1 nm or larger). The nanoparticles do not have significant active groups on their surfaces, whereas the radicals remain active, and thus, the nanoparticles can serve as nano-building blocks and the radicals can serve as adhesives. The nanoparticles may have active groups on their surfaces upon formation of the nanoparticles (this may be the reason that the nanoparticles are capable of being strongly coagulated each other); however, while being transferred to the substrate surface, the nanoparticles lose the active groups from their surfaces (this may be the reason that a film is not formed under conditions where nanoparticles exist predominantly over radicals).

In step (III), the density and dielectric constant of a film may be controlled by the ratio of the nanoparticle flux to the radical flux so that the nanoparticles and the radicals can be co-deposited on the substrate at a controlled ratio where the nanoparticles (the nano-building blocks) are polymerized using the radicals (the adhesives). The flux ratio can be controlled by the thermal gradient between the substrate and the upper electrode, wherein thermophoretic force due to the temperature gradient drives the nanoparticles toward a place having a lower temperature (e.g., the upper electrode if the lower electrode's temperature is higher), thereby controlling the nanoparticles flux. In the present invention, the theories explained above or later are not intended to limit the present invention; however, in some embodiments, the theories can apply and characterized the embodiments.

In the above, the temperature gradient can be defined as |Ts−Tp|/L wherein Ts is a temperature of the substrate, Tp is a temperature of the upper electrode, |Ts−Tp| is an absolute value of the difference between Ts and Tp, and L is a distance between the substrate and the upper electrode. Ts may be substantially close to the temperature of the lower electrode. In that case, the temperature of the lower electrode can be used as Ts. In an embodiment, Ts can be calculated from the temperature of the lower electrode using an equation predetermined through experiments. Ts and Tp are surface temperatures which can be directly or indirectly measured, e.g., determined based on temperatures detected by temperature-measuring devices embedded in the lower and upper electrodes. Further, Ts and Tp may be the average temperatures on the respective surfaces if temperatures are measured at multiple locations. L is the distance between the substrate and the upper electrode and may be substantially close to the distance between the lower electrode and the upper electrode. Depending on the thickness of the substrate and the configuration of the lower electrode, in an embodiment, the distance between the lower electrode and the upper electrode can be used as L, or L can be calculated from that distance. In an embodiment, the lower electrode is a susceptor on which the substrate is placed, and the upper electrode is a showerhead which serves as a powered electrode. However, the terms “upper” and “lower” can be equal to “first” and “second”, respectively, and their geographical locations can vary. The upper and lower electrodes can be angled electrodes or can be side electrodes.

In the present invention, steps (I) and (II) and similar steps can be conducted according to the steps disclosed in U.S. patent application Ser. No. 10/990,562, filed Nov. 17, 2004, which is commonly owned by the assignees of the present application, and the disclosure of which is incorporated herein by reference in its entirety.

The above-mentioned embodiment at least includes the following aspects, but the present invention is not limited to these aspects:

The temperature gradient may be controlled to satisfy −10≦(Ts−Tp)/L≦50, including 0≦(Ts−Tp)/L≦50, 5≦(Ts−Tp)/L≦40, 10≦(Ts−Tp)/L≦30, and combinations of the foregoing, wherein Ts is a temperature of the substrate (° C.), Tp is a temperature of the upper electrode (° C.), and L is a distance between the substrate and the upper electrode (cm).

In an embodiment, in the depositing step, the upper electrode may be controlled at a temperature of about 50° C. to about 250° C., including 100° C., 150° C., 200° C., and ranges between any two numbers of the foregoing.

In an embodiment, the upper and lower electrodes may be set apart at a distance of about 5 mm to about 30 mm, including 10 mm, 15 mm, 20 mm, 25 mm, and ranges between any two numbers of the foregoing; preferably 5 mm to 20 mm.

In an embodiment, a film being formed by the deposited nanoparticles may have a dielectric constant of about 1.2 to about 3.5, including 1.3, 1.5, 1.7, 2.0, 2.2, 2.5, 3.0, and ranges between any two numbers of the foregoing. In an embodiment, porosity of a film being formed may be in the range of about 0% to about 80%, including 10%, 30%, 50%, 70%, and ranges between any two numbers of the foregoing. For example, a film has a dielectric constant of 1.7-3.5 which may corresponds to a porosity of 60%-0% (calculated from the weight and volume of the film). In general, the higher the temperature of the lower electrode with respect to that of the upper electrode, the higher the dielectric constant of the film being formed becomes. That is, the dielectric constant of the film being formed can be controlled as a function of the temperature gradient between the substrate and the upper electrode, and the dielectric constant of the film being formed can be reduced by reducing the temperature of the substrate.

In another aspect, the present invention provides a method for forming a low dielectric constant film, comprising the steps of: (i) introducing reaction gas comprising an organo Si gas and an inert gas into a reactor of a capacitively-coupled CVD apparatus; (ii) adjusting a flow rate of reaction gas so as to satisfy a relational expression below

$$\frac{P \times L \times N \times A}{Q} < 0.1$$

Q: Gas flow rate (sccm)
N: Number of gas nozzles of the shower plate
A: Cross sectional area of a gas nozzle of the shower plate (cm²)
P: Pressure inside the reactor (Torr)
L: Electrode interval (cm);
   (iii) adjusting a size of fine particles being generated from the organo Si gas in the vapor phase to a size of about 10 nm or below as a function of a plasma discharge period in the reactor; and (iv) depositing the fine particles generated on a substrate being placed between upper and lower electrodes inside the reactor by stopping plasma discharge while controlling a temperature gradient between the substrate and the upper electrode at about 100° C./cm or less.

In yet another aspect, the present invention provides a method for forming a low dielectric constant film comprising the steps of: (A) introducing reaction gas comprising an organo Si gas and an inert gas into a reactor; (B) forming fine particles from the organo Si gas by executing plasma discharge for about 100 msec. to about 2 sec.; and (C) depositing the fine particles onto a substrate being placed between upper and lower electrodes inside the reactor while controlling a temperature gradient between the substrate and the upper electrode at about 100° C./cm or less.

In still another aspect, the present invention provides a method for forming a low dielectric constant film comprising the steps of: (A) introducing reaction gas comprising an organo Si gas and an inert gas into a reactor and executing plasma discharge for forming nanoparticles from the organo Si gas; and (B) depositing nanoparticles on a substrate placed between upper and lower electrodes in the reactor by controlling the time required for forming nanoparticles from the organo Si gas (T1), while controlling a temperature gradient between the substrate and the upper electrode at about 100° C./cm or less, the time required for transporting nanoparticles formed to the substrate being placed inside the reactor (T2), and the time until coagulation growth takes place between nanoparticles during transport (T3) as functions of a plasma discharge period and a gas flow rate.

In another aspect, the present invention provides a method for forming a low dielectric constant film comprising the steps of: (A) introducing reaction gas comprising an organo Si gas and an inert gas into a reactor and executing plasma discharge for forming nanoparticles from the organo Si gas; and (B) controlling deposition of nanoparticles onto a substrate placed between upper and lower electrodes in the reactor using the time required for forming nanoparticles from the organo Si gas (T1), the time required for transporting nanoparticles formed to the substrate being placed inside the reactor (T2), and the time until coagulation growth takes place between nanoparticles during transport (T3) as control parameters, while controlling a temperature gradient between the substrate and the upper electrode at about 100° C./cm or less.

In the above, in step (B), T1, T2 and T3 may be controlled to become nearly T1=0.1-1 sec. and T2<T3, or nearly T1=0.1-1 sec., T1=T2 and T3=0.

In all of the aforesaid embodiments and aspects, any element used in an embodiment can interchangeably be used in another embodiment unless such a replacement is not feasible or causes adverse effect. Further, the present invention can equally be applied to apparatuses and methods.

The present invention further includes, but is not limited to, the following additional embodiments.

A flow rate of the organic gas may be 10% or below as against a flow rate of the inert gas; a flow rate of the organic gas may be 5% or below as against a flow rate of the inert gas; plasma discharge may be executed by applying RF power at about 8 W/cm² to about 13 W/cm² a pressure inside the reactor during plasma discharge may be about 0.1 Torr to about 10 Torr; a flow velocity of the reaction gas may be adjusted to 2.5 cm/sec. or below in a direction parallel to an electrode surface inside the reactor (generally, a direction parallel to a substrate surface); a substrate temperature during the deposition may be within the range of about 0° C. to about 450° C.

Additionally, the plasma discharge may be executed using RF power at 13.56 MHz, 27 MHz or 60 MHz. The plasma discharge may be executed using VHF power at 100 MHz or above. VHF power may be applied from a spoke antenna electrode. The plasma discharge may be executed by applying RF power and an impedance of RF power may be adjusted by an electronic RF matching box.

The organo Si gas contains Si_{α}O_{α-1}R_{2α-β+2}(OCₙH₂ₙ₊₁)_{β} (wherein α is an integer of 1-3, β is 0, 1, 2, 3 or 4, n is an integer of 1-3, and R is C₁₋₆ hydrocarbon attached to Si), SiR_{4-α}(OCₙH₂ₙ₊₁)_{α} (wherein α is 0, 1, 2, 3 or 4, n is an integer of 1-3, and R is C₁₋₆ hydrocarbon attached to Si), Si₂OR_{6-α}(OCₙH₂ₙ₊₁)_{α} (wherein α is 0, 1, 2, 3 or 4, n is an integer of 1-3, and R is C₁₋₆ hydrocarbon attached to Si), SiH_{β}R_{4-α}(OCₙH₂ₙ₊₁)_{α-β} (wherein α is 0, 1, 2, 3 or 4, β is 0, 1, 2, 3 or 4, n is 1 or 2, and R is C₁₋₆ hydrocarbon attached to Si); for example, one or a combination of multiple gases selected from the group consisting of Si(CH₃)₄, Si(CH₃)₃(OCH₃), Si(CH₃)₂(OCH₃)₂, Si(CH₃)(OCH₃)₃, Si(OCH₃)₄, Si(CH₃)₃(OC₂H₅), Si(CH₃)₂(OC₂H₅)₂, Si(CH₃)(OC₂H₅)₃, Si(OC₂H₅)₄, SiH(CH₃)₃, SiH₂(CH₃)₂, SiH₃(CH₃).

As an inert gas, Ar or one of gases selected from the group consisting of He, Ne, Kr, Xe and N₂ or a combination thereof may be used. The reaction gas further may contain an oxidizing gas containing at least one selected from the group consisting of O₂, CO, CO₂, and N₂O for adjusting a carbon concentration of a thin film formed.

Furthermore, fine particles may be formed by setting a single round of plasma discharge period at about 1 msec. to about 1 sec.; plasma discharge may be stopped during a period when the fine particles are deposited on a substrate. Or, by making up one cycle of the steps of forming fine particles by setting a plasma discharge period at about 10 msec. to about 1 sec. and stopping plasma discharge after a single round of plasma discharge for about 100 msec. to about 2 sec. while fine particles generated are deposited on the substrate, at least two cycles or more may be executed.

In the case of intermittent discharge processing (pulsed discharge), with a configuration in which the reaction gas is introduced into the reactor through a gas nozzles of a shower plate, plasma is excited in a reaction region between the upper and lower electrodes and a substrate is placed on the lower electrode, a flow rate of the reaction gas may be adjusted so as to satisfy the following relational expression:

$$\frac{P \times L \times N \times A}{Q} < 0.1$$

Q: Gas flow rate (sccm)
N: Number of gas nozzles of the shower plate
A: Cross sectional area of a gas nozzle of the shower plate (cm²)
P: Pressure inside the reactor (Torr)
L: Electrode interval (cm)

Additionally, regardless of whether discharge is pulsed or not, a gas stream may be adapted to be pulsed. Or, a gas stream may be adjusted to be increased when nanoparticles generated are transported to a substrate.

As a post-treatment, by comprising a step of curing a film formed by thermal treatment using plasma processing, or combining with UV or EB after the deposition, the film's mechanical strength can be improved. Or, improving the film's mechanical strength can be achieved by comprising a step of adhering organo silicon molecules onto the film by letting the substrate stand in an organo silicon gas atmosphere, and a step of curing the film after the deposition. Or, improving the film's mechanical strength can also be achieved by conducting a step of letting the substrate stand in an H₂O gas atmosphere and a step of letting the substrate stand in an organo silicon gas atmosphere once each or repeatedly multiple times after the deposition.

Additionally, by making up one cycle of the steps of forming fine particles by setting a plasma discharge period at about 10 msec. to about 1 sec. and stopping plasma discharge after a single round of plasma discharge for about 100 msec. to about 2 sec. and depositing the fine particles generated on the substrate, at least two cycles or more may be executed; a low-k film may be formed by consecutively repeating the cycle 30 to 150 times. The number of cycles may be adjusted appropriately according to a desired film thickness; the cycle can be executed the different number of times including 5, 50, and 100 cycles. Additionally, the cycle can also be executed once (without repetition).

In one embodiment, T1, T2 and T3 are controlled so as to achieve nearly T1=0.1-1 sec. and T2<T3. In order to achieve this goal, for example, using pulsed plasma discharge, one round of plasma discharge ON period is set at about 0.1 sec. to about 1 sec. and one round of plasma discharge OFF period is set at about 10 msec. to about 100 msec. during which transporting nanoparticles generated onto the substrate has been completed (Pulsed discharge). During the period when plasma discharge is stopped, nanoparticles are transported to the substrate at nearly the same velocity as a gas flow velocity because nanoparticles' electrostatic force does not act on. Additionally, during that period of time, nanoparticles' coagulation growth advances. Because nanoparticles are charged during plasma discharge and their electrostatic force resists to viscosity by the gas flow velocity, their electrostatic force is apt to be detained in a particle growth region. Consequently, in this case, the growth stage and the transport stage of the nanoparticles can be separated; i.e., plasma is excited only for a period of time required for nanoparticle formation, and after that, plasma discharge is stopped before nanoparticles' coagulation growth advances and the nanoparticles are released, and a gas flow rate is adjusted so as to transport the nanoparticles onto the substrate.

Additionally, in one aspect, T1, T2 and T3 are controlled so as to achieve nearly T1=0.1-1 sec., T1=T2, T3=0. In order to achieve this goal, for example, continued plasma discharge is used (Coagulation growth can be ignored because it is suppressed during plasma excitation.), and nanoparticles are adapted to reach at a substrate surface upon becoming an appropriate size. In this case, the growth stage and the transport stage of the nanoparticles cannot be separated. Nanoparticles are transported during their formation. Additionally, because plasma discharge is continued during the transport, a gas stream at a relatively high velocity (in a direction perpendicular to an electrode surface) becomes required in order to transport the nanoparticles.

An average size of the fine particles may also be about 1 nm to about 10 nm. A dielectric constant of a film formed may also be 2.4 or below; porosity of a film formed may also be about 40% to about 80%.

Additionally, for purposes of summarizing the invention and the advantages achieved over the prior art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

Figures are referred to when preferred embodiments of the present invention are described, but the present invention is not limited to these figures and embodiments.

FIG. 1 is a view showing a frame format of a parallel flat-plate type capacitively-coupled CVD apparatus which can be used in the present invention. The figure is oversimplified for explanation purposes.

FIG. 2 is a graph showing dependency of a plasma discharge period on a nanoparticle size in one embodiment of the present invention.

FIG. 3 is a graph showing relation between a nanoparticle size and the time required for transporting nanoparticles when a transport distance by diffusion is set at 1 cm in one embodiment of the present invention.

FIG. 4 is a graph showing relation between nanoparticles' coagulation time and a nanoparticle size in one embodiment of the present invention.

FIG. 5 is a view showing a frame format of a spoke antenna electrode, which can be used in one embodiment of the present invention. The figure is oversimplified for explanation purposes.

FIG. 6 is a schematic diagram showing a concept of bottom-up nanofabrication method using nano-building blocks (nanoparticles) and adhesives (radicals) according to an embodiment of the present invention.

FIGS. 7A, 7B, and 7C are schematic diagrams showing the nanoparticle flux and the radical flux when Ts<Tp, Ts=Tp, and Ts>Tp, respectively, according to an embodiment of the present invention.

FIG. 8 is a graph showing the dependence of film density on the temperature gradient between electrodes according to an embodiment of the present invention.

FIG. 9 is a graph showing the dependence of dielectric constant on the temperature gradient between electrodes according to an embodiment of the present invention.

### DETAILED DESCRIPTION OF THE PREFERRED EMBODIMENT

Preferred embodiments of the present invention are explained below. The present invention is not limited to these embodiments. It will be understood by those skilled in the art that numerous and various modifications can be made without departing from the spirit of the present invention. Therefore, it should be clearly understood that the forms of the present invention are illustrative only and are not intended to limit the scope of the present invention.

Nanoparticles (as nano-building blocks) and radicals (as adhesives) can be produced in a gas phase using a reactive plasma (nano-building block production phase), and then the blocks and adhesives are co-deposited on a substrate (nano-construction phase). The size of nanoparticles can be controlled by the duration of RF discharges (e.g., pulsed RF discharges), and the density and dielectric constant can be controlled by the ratio of the nanoparticle flux to the radical flux. First, the nano-building block production phase will be described, and thereafter, the nano-construction phase will be described.

When insulating fine particles are formed by plasma CVD, it is generally difficult to form insulating fine particles with a diameter of 10 nm or below in the vapor phase stably because RF power is apt to get locally concentrated on under the condition of particle generation. Additionally, in the present invention, a diameter of a nanoparticle is about 1 nm to tens nm; preferably about 1 nm to about 20 nm; more preferably 10 nm or below. Additionally, nanoparticles do mean not only individual particles but also particle groups; in the case of a particle group, it is desired that all particles comprising a group are nanoparticles; however, not applying only to the aforementioned, it is preferable that particles formed have particle size distribution and comprise groups of fine particles whose average particle diameter is about 1 nm to about 10 nm.

According to one aspect of the present invention, while a dilution ratio of a source gas (a ratio of a source gas flow rate to the entire gas flow rate) is decreased (e.g., 5% or below) using an organo Si-containing gas as a source gas, and a reaction time for forming nanoparticles in the vapor phase is secured by increasing a gas pressure to e.g., about 0.5 Torr or above and decreasing a gas flow velocity (in a direction parallel to an electrode surface) in a discharge region to e.g., 2.5 cm/sec. or below, by discharging electricity within a time frame before nanoparticles generated begin coagulating and yet by applying high RF power (e.g., about 4 W/cm² or above) to a region between the electrodes, particles are caused to be formed in the vapor phase and to be deposited on the substrate.

Control parameters in the above-mentioned embodiment include a dilution ratio, flow velocity, flow rate of a source gas, a pressure inside the reactor, RF voltage, and discharge period.

Additionally, film formation can also be controlled using upper-ranking parameters in addition to the above-mentioned control parameters. As mentioned before, one embodiment of the method for forming low dielectric constant films using nanoparticles includes the steps of: (A) introducing reaction gas comprising an organo Si gas and an inert gas into a reactor and executing plasma discharge for forming nanoparticles from the organo Si gas; and (B) depositing nanoparticles on the substrate by controlling the time required for forming nanoparticles from the organo Si gas (T1), the time required for transporting nanoparticles generated to the substrate being placed inside the reactor (T2), and the time until coagulation growth takes place between nanoparticles during transport (T3). Consequently, in one embodiment, the film formation can be controlled by the above-mentioned T1, T2 and T3.

In order to control a nanoparticle size, controlling the detention time in a particle-growth region (in the vicinity of a region defined by a plasma sheath boundary) of the nanoparticles in plasma becomes necessary. In one example, nanoparticles' detention time is controlled so as to obtain nearly T1=0.1-1 sec., T2<T3. This can be achieved, for example, as follows using the plasma discharge period and a gas stream as sub-parameters: Using pulsed plasma discharge, one round of discharge ON period is set at about 0.1 sec. to about 1 sec.; one round of discharge OFF period is set at about 10 msec. to about 100 msec. during which transporting nanoparticles onto the substrate is adapted to be completed. During a period when plasma discharge is stopped, because nanoparticles' electrostatic force does not act on, nanoparticles are transported to the substrate at nearly the same velocity as a gas flow velocity. Additionally, during that period of time, nanoparticles' coagulation growth advances. Because nanoparticles are charged during plasma discharge and their electrostatic force resists to viscosity by the gas flow velocity, their electrostatic force is apt to be detained in a particle growth region. In other words, particles are apt to be detained in a particle growth region (a sheath region) during the discharge. Additionally, coagulation of nanoparticles charged in plasma is suppressed by repellent Coulomb force between the particles of nanoparticles. Consequently, in this case, the growth stage and the transport stage of the nanoparticles can be separated; i.e., plasma is excited only for a period of time required for nanoparticle formation, and after that, plasma discharge is stopped to cause sheath to disappear, and a gas flow rate is adjusted so as to complete transporting nanoparticles formed onto the substrate before nanoparticles' coagulation growth advances.

Additionally, the smaller the nanoparticle size, the less the electrostatic force caused by charged nanoparticles becomes. Consequently, the faster a gas stream is, the more the number of fine particles exiting from the particle growth region before they grow in the region becomes. Fine particles beginning growing increase their electrostatic force caused by being charged and are more apt to be detained in the region. From this, nanoparticles depositing on the substrate becomes to have a certain range of particle size distribution, and it becomes difficult for nanoparticles having a size of below 0.1 nm to deposit. If depositing particles of a small size is desired, it can be achieved by increasing a growth rate of nanoparticles or decreasing a gas flow velocity.

As described in detail later, coagulation growth is a function of a type, concentration, etc. of a source gas contained in reaction gas; from the viewpoint of processing, generally, it does not affect significantly if treating the coagulation time of about 0.1 sec. as a standard condition.

In examples except the above-mentioned, T1, T2 and T3 are controlled so as to achieve nearly T1=0.1-1 sec., T1=T2, and T3=0. This can be achieved as follows using the plasma discharge period and a gas flow as sub-parameters: In other words, not using pulsed discharge as used in the above, this is achieved by continued plasma discharge. Using continued plasma discharge (coagulation growth can be ignored because it is suppressed during plasma discharge by repellent Coulomb force between the particles), nanoparticles are adapted to reach a substrate surface after their size has become appropriate in the particle growth region. In this case, because the sheath in the particle growth region continues to be present, particles need viscosity of a large gas stream larger than electrostatic force. The growth stage and the transport stage of the nanoparticles cannot be separated as can be with the pulsed discharge. Consequently, a relatively large gas stream is required; in order to transport nanoparticles while surpassing electrostatic force, a transport velocity of particles becomes slower than a gas flow velocity. A gas flow velocity (perpendicular to an electrode surface) required for increasing viscosity by a gas stream larger than nanoparticles' electrostatic force is, for example, about 0.2 sec., about 0.1 sec., about 0.05 sec., or about 0.025 sec. (including numerical values between the foregoing) at which the gas streams through the electrode interval, which respectively correspond to about 20 cm/sec., about 40 cm/sec., about 80 cm/sec., or about 160 cm/sec. in case of the electrode interval of 40 cm.

Other parameters are explained below. If not otherwise specified, parameters are common to pulsed charge and continued charge.

A dilution ratio of a source gas is lowered so as to maintain high-density plasma excited from an inert gas such as Ar. If a ratio of a source gas becomes high, plasma density drops and radical density required for nanoparticle formation may not be achieved. As an inert gas, Ar or one of gases selected from the group consisting of He, Ne, Kr, Xe and N₂ or a combination thereof can be used. A dilution ratio of a source gas is, for example, about 0.1% to about 40% (including 0.2%, 0.5%, 1%, 2%, 3%, 4%, 5%, 10%, 20%, and numerical values between the foregoing); preferably about 0.3% to about 8%; more preferably about 0.5% to about 3%.

As a source gas, an organo Si gas at least containing Si and comprising C, O and H in addition to Si is used. As a formula, an organo Si gas expressed by Si_{α}H_{β}O_{γ}C_{λ} (wherein α, β, γ, λ are any integers); for example, an organo Si gas expressed by Si_{α}O_{α-1}R_{2α-β+2}(OCₙH₂ₙ₊₁)_{β} (wherein α is an integer of 1-3, β is 0, 1, 2, 3 or 4, n is an integer of 1-3, and R is C₁₋₆ hydrocarbon attached to Si) can be mentioned. Furthermore, organo Si gases expressed by SiR_{4-α}(OCₙH₂ₙ₊₁)_{α} (wherein α is 0, 1, 2, 3 or 4, n is an integer of 1-3, and R is C1-6 hydrocarbon attached to Si), Si₂OR_{6-α} (OCₙH₂ₙ₊₁)_{α} (wherein α is 0, 1, 2, 3 or 4, n is an integer of 1-3, and R is C₁₋₆ hydrocarbon attached to Si), and SiH_{β}R_{4-α}(OCₙH₂ₙ₊₁)_{α-β} (wherein α is 0, 1, 2, 3 or 4, β is 0, 1, 2, 3 or 4, n is 1 or 2, and R is C₁₋₆ hydrocarbon attached to Si) can be mentioned. As a preferred organo Si gas, one or a combination of multiple gases selected from the group consisting of Si(CH₃)₃(OCH₃), Si(CH₃)₂(OCH₃)₂, Si(CH₃)(OCH₃)₃, Si(OCH₃)₄, Si(CH₃)₄, Si(CH₃)₃(OC₂H₅), Si(CH₃)₂(OC₂H₅)₂, Si(CH₃)(OC₂H₅)₃, Si(OC₂H₅)₄, SiH(CH₃)₃, SiH₂(CH₃)₂, SiH₃(CH₃) can be used.

When the gas mentioned above whose molecules do not contain an oxygen atom is used, an SiOCH-containing film is formed if an oxidizing gas is further added; a SiC-containing film is formed if an oxidizing gas is not added. Additionally, by adding an oxidizing gas such as O₂, CO, CO₂ and N₂O, a carbon concentration of a film formed can be adjusted (to an approx. 0-50% extent).

A flow velocity parallel to an electrode surface is set at a velocity at which a time of period required for nanoparticle growth can be secured. If a flow velocity is higher, nanoparticles flow out from the electrode surface before they have grown. By retaining a source gas in a nanoparticle growth region in plasma (e.g., between upper and lower electrodes) for a certain period of time, growth of nanoparticles is promoted. As the nanoparticles grow, they are apt to be charged. If a gas velocity is high, nanoparticles flow out from the electrode surface before they have grown, or charged nanoparticles are apt to be evacuated to outside the nanoparticle growth region without being deposited on the substrate. A gas velocity is, for example, about 5 cm/sec. or below (including 4 cm/sec., 3 cm/sec., 2 cm/sec., 1 cm/sec., 0.5 cm/sec., 0.25 m/sec. and numerical values between the foregoing); preferably 2.5 cm/sec. or below; more preferably about 1 cm/sec. or below.

Additionally, grown nanoparticles, subsequently, need to be transported to the substrate and to be deposited. If a gas velocity is small, as described later, a transport speed is controlled by a diffusion phenomenon. However, a transport speed by the diffusion phenomenon is small. The lower a pressure is and the smaller a particle diameter is, the more a transport speed by the diffusion phenomenon increases. Because collision chances of molecules decrease if a pressure is low, nanoparticle growth is difficult to advance sufficiently. Additionally, there may be a case in which smaller particles are transported first, hence nanoparticles may not grow sufficiently. Furthermore, because nanoparticles coagulate/grow during transport, transporting nanoparticles to the substrate before their coagulation growth advances is desired.

When a transport speed by the diffusion phenomenon and the coagulation growth time are compared, in an ordinary reactor, nanoparticles' coagulation growth can be started before nanoparticles reach the substrate by the diffusion phenomenon. Therefore, except an embodiment in which an electrode interval is extremely short (e.g., 10 mm or below; further 5 mm or below) so as to make transport by diffusion dominant, it is desirable that nanoparticles are forcibly transported onto the substrate by a gas stream. As described later, the relation between the coagulation growth time (τ_{c}) and a Gas flow rate (Q) can be expressed as follows:

$$Q > \frac{P \times L \times N \times A}{{τ}_{c}}$$

Q: Gas flow rate (sccm)
τ_{c}: Coagulation growth time (sec.)
N: Number of gas nozzles of the shower plate
A: Cross sectional area of a gas nozzle of the shower plate (cm²)
P: Pressure inside the reactor (Torr)
L: Electrode interval inside the reactor (cm)

By supplying a gas flow rate so as to satisfy the above-mentioned conditions, nanoparticles can be effectively deposited on the substrate. Preferably, a gas is supplied at about 1.1 times as much as Q, which is the minimum value satisfying the above-mentioned formula, to about 30 times (including 1.5 times, 2 times, 5 times, 10 times, 15 times, 20 times and numerical values between the foregoing). However, it is preferable that a gas flow rate is controlled so as to achieve the above-mentioned gas flow velocity or below (in a direction parallel to the electrode surface).

A pressure inside the reactor is a pressure at which source gas molecules required for nanoparticle formation can be secured. Because nanoparticle growth is vapor phase epitaxy, a pressure at which vapor phase collision takes place sufficiently is preferable. If a pressure is low, diffusion loss of extremely small nanoparticle precursors occurs. A pressure inside the reactor is, for example, 0.1 Torr or above (including 0.2 Torr, 0.3 Torr, 0.4 Torr, 0.5 Torr, 1 Torr, 2 Torr, 5 Torr, 10 Torr, 15 Torr and numerical values between the foregoing); preferably about 0.5 Torr to about 10 Torr; more preferably about 1 Torr to about 5 Torr.

RF voltage used should be able to secure radical density required for nanoparticle formation and may be, for example, at 1 W/cm² or above (including 2 W/cm², 3 W/cm², 4 W/cm², 5 W/cm², 7 W/cm², 10 W/cm², 15 W/cm², 20 W/cm², and numerical values between the foregoing); preferably at about 4 W/cm² or above; more preferably at about 8 W/cm² to about 13 W/cm².

RF power used is at 2 MHz or above in one embodiment; for example, RF power of 13.56 MHz, 27 MHz, 60 MHz, etc. is used.

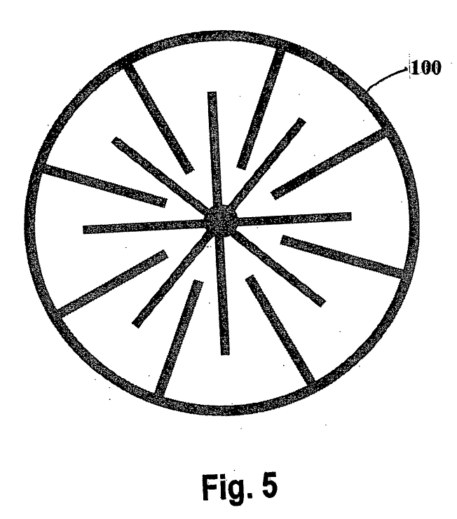

Furthermore, in order to increase the plasma density, VHF power at 100 MHz or above can be used. Additionally, by using VHF power, discharge voltage is lowered, thereby enabling to reduce an effect on coagulation of charged nanoparticles in the vapor phase. By this, a large quantity of nanoparticles can be generated. VHF power can be easily realized by using a spoke antenna electrode 100 shown in FIG. 5 as an upper electrode in place of a plain conductive parallel flat-plate normally used for plasma CVD. When used with RF power at 1 MHz to 50 MHz, VHF power takes care of about 2% to about 90% of the entire power (including 5%, 10%, 20%, 50%, 70%, and numerical values between the foregoing); preferably about 5% to about 20%.

Additionally, impedance inside the reactor always changes according to flow of a source gas and a reaction taking place. Consequently, it is desirable to adjust RF circuit-related impedance balance including a power source and load (i.e., the reactor) all the time. As a matching box, a regular matching box, an electronic RF matching box, etc. can be used. In the case of a regular matching box, because the impedance is matched by controlling the impedance by changing condenser capacity mechanically using a stepping motor, it generally takes several second to match the impedance. In the case of an electronic matching box, because impedance control is made electronically, the impedance can be matched at a high speed of microseconds as compared with a mechanical method. As a method of making the impedance control electrically, there are methods such as changing the condenser capacity electrically or changing the coil inductance electrically.

The discharge period is a period of time appropriate for nanoparticle growth. A fine particle size can be controlled by adjusting the discharge period. In a standard state (described later), the discharge period can be adjusted within the range of about 0.1 second to about 1 second and a fine particle size can be adjusted up to about 1 nm to about 10 nm. In one embodiment, the relation between the discharge period and a particle size is nearly linear. In another embodiment, by making up one cycle of the steps of forming nanoparticles by applying a RF voltage for about 1 sec. (including 5 msec., 10 msec., 50 msec., 100 msec, 0.2 sec., 0.5 sec., and numerical values between the foregoing) and depositing nanoparticles formed by turning OFF the RF voltage while particles generated are transported, for example, for about 0.2 sec. to about 3 sec. (including 0.05 sec., 0.1 sec., 0.5 sec., 1 sec., 2 sec., and numerical values between the foregoing), a thin film is formed by repeating this cycle. The cycle may be fixed or may be changed each time. Because a transport speed during a period when the RF voltage is turned off is not much affected by a nanoparticle size and stays constant if transporting nanoparticles by the gas stream is dominant, by adjusting a particle size by adjusting only the length of time of applying the RF voltage, insulating Si particles (SiO-containing, SiC-containing insulator, etc.) of different sizes can be multi-layered one by one. The number of cycles for the deposition step may be once and more; or it may not be cycle operation, but may be continued operation. In the case of continued operation, it is desirable to execute the deposition by a gas stream and transporting nanoparticles should be completed before nanoparticles have overgrown.

As explained above, the size of nanoparticles can be controlled by the duration of RF discharges. the density and dielectric constant can be controlled by the ratio of the nanoparticle flux to the radical flux. The flux ratio can be controlled by a thermal gradient between the substrate and the upper electrode. FIG. 6 is a schematic diagram showing a concept of bottom-up nanofabrication method using nano-building blocks (nanoparticles) and adhesives (radicals) according to an embodiment of the present invention. Due to the RF discharges, the source gas molecules are excited and generate radicals. The size of radicals is normally about 0.5 nm or less, and nanoparticles are generated by polymerization of radicals. Upon formation of nanoparticles, the nanoparticles have active groups on their surfaces and may strongly coagulate together. However, when the nanoparticles are deposited on the substrate, they do not coagulate or are not polymerized by themselves (no film is formed). That is, the nanoparticles lose the active groups while being transferred to the substrate. On the other hand, the radicals remain active and can serve as adhesives. The nanoparticles can be polymerized together using the radicals as adhesives on the substrate. Thus, by changing the supply of the nanoparticles and the supply of the radicals to the substrate, it is possible to change the structure of a film.

Thermophoretic force (Fₜₕ) exerted on fine particles can be expressed by the following equation if the diameter of a fine particle (d) is smaller than a mean free path (λ) (about 70 μm for Ar gas at 1 Torr, 100° C.=373K):

$${F}_{th} = \frac{- p λ {d}^{2} ∇ T}{T} \qquad ( 1 )$$

wherein p is gas pressure [dyn/cm2], and T is gas temperature [K].

The minus sign in the equation indicates that thermophoretic force is directed from a high temperature side to a low temperature side. The temperature gradient (VT) is substantially or nearly constant and can be expressed by the following equation, wherein Ts is a temperature of the substrate (° C.), Tp is a temperature of the upper electrode (° C.), and L is a distance between the substrate and the upper electrode (cm):

$$∇ T = \frac{{T}_{s} - {T}_{p}}{L} \qquad ( 2 )$$

As is understood from Equation (1), because the thermophoretic force is proportional to the square of the fine particle size, small particles such as atoms, molecules, and radicals are not significantly affected by the thermophoretic force. On the other hand, nanoparticles having a size of 1-20 nm, for example, are affected by the thermophoretic force. Thus, by controlling the thermophoretic force, i.e., the temperature gradient, it is possible to control transfer of nanoparticles (the nanoparticle flux) predominantly over that of radicals (the radical flux).

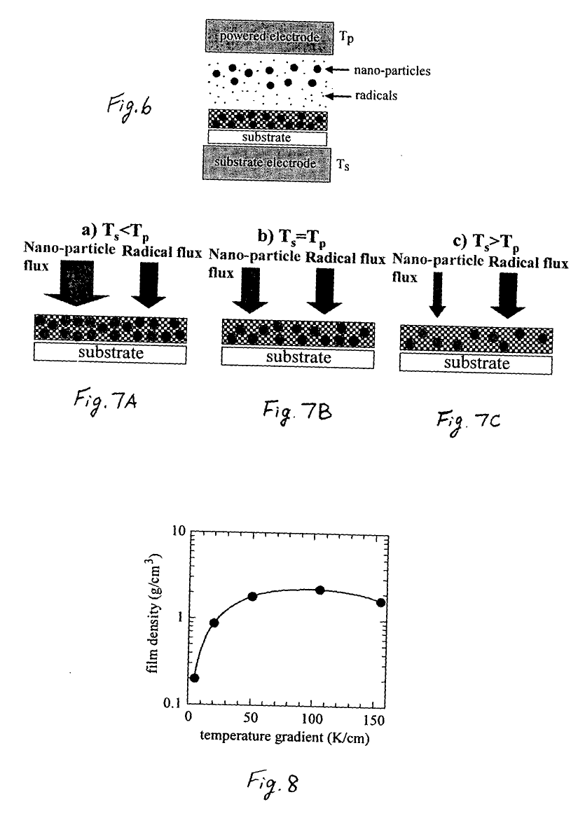

FIGS. 7A, 7B, and 7C are schematic diagrams showing the nanoparticle flux and the radical flux when Ts<Tp, Ts=Tp, and Ts>Tp, respectively, according to an embodiment of the present invention. When Ts<Tp (FIG. 7A), the thermophoretic force is exerted on the nanoparticles toward the lower electrode, thereby increasing the nanoparticle flux. As a result, a film having high porosity or low dielectric constant (close to one) can be formed. However, because the thermophoretic force dominates the nanoparticle flux and insufficient radicals (adhesives) are transferred to a film as compared with the nanoparticles, the film may not have sufficient structural strength. When Ts=Tp (FIG. 7B), no thermophoretic force is significant, and diffusion dominates both the nanoparticle flux and the radical flux. When Ts>Tp (FIG. 7C), the thermophoretic force is exerted on the nanoparticles toward the upper electrode, thereby reduce the nanoparticle flux to the substrate. As a result, a film having low porosity or high dielectric constant (on the order of 3 or 4) can be formed.

By conducting post-treatment after the deposition, film properties can be improved. For example, in order to improve the film's mechanical strength, curing a film deposited can be done by thermal treatment combining with UV and EB after the deposition. Thermal treatment can be executed at a temperature, e.g., about 300° C. to about 450° C. for about 10 sec. to about 5 min. in a vacuum.

Additionally, in order to improve the film's mechanical strength, a cure step can be conducted by thermal treatment thermal treatment combining with plasma processing, UV or EB. Plasma processing as post-treatment may be conducted in the atmosphere of H2 and He under the conditions of RF power of about 27 MHz at about 200 W to about 500 W and a pressure of about 1 Torr to about 6 Torr in the case of 200 mm wafers.

Furthermore, the film's mechanical strength can also be improved by conducting the steps of adhering organo silicon molecules to a fine-particle film by letting the film stand in the organo silicon gas atmosphere after the fine-particle film is formed and of curing the film. For example, curing of the film deposited can be executed at 350-450° C. after a silicon wafer is placed inside a vacuum reactor and about 10 sccm to about 500 sccm of an organo silicon gas having SiOCH composition is introduced into the reactor with a wafer temperature being set at about 0° C. to about 250° C. Additionally, in the cure step, UV may be used together. A film cured becomes an SiOH-containing film.

Or, after fine-particle film is formed, the film's mechanical strength can be improved by repeating the steps of letting the film stand in the H₂O gas atmosphere and letting the film stand in the organo silicon gas atmosphere on short cycle or multiple times. For example, before organo silicon gas is introduced, about 1 sccm to about 500 sccm of H₂O gas can be introduced.

An elastic modulus of a film formed is about 1 GPa to about 4 GPa in one embodiment and is improved by about 10% to about 50% after the film is cured.

Apparatus Configuration

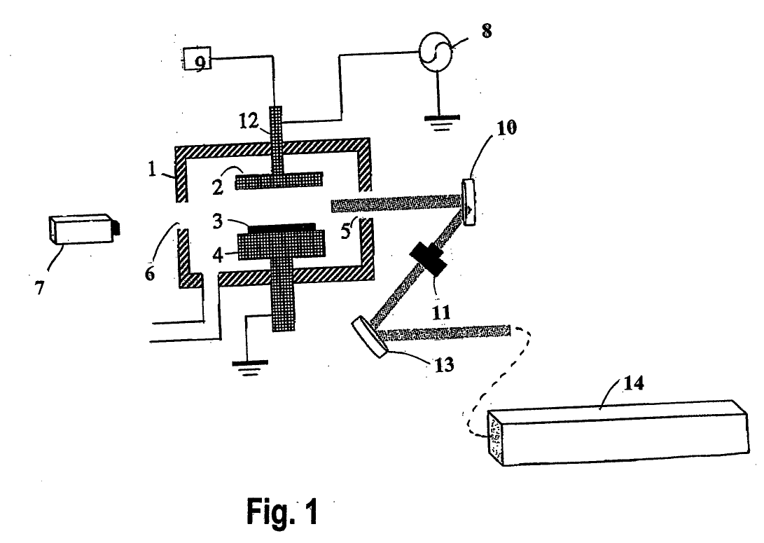

In FIG. 1, an example of a parallel flat-plate type capacitively-coupled CVD apparatus which can be used in the present invention is shown. The present invention is not limited to this apparatus. Additionally, the figure is oversimplified for the purpose of explanation. Additionally, although this apparatus includes a nanoparticle-measuring device, providing such device is not necessary for commercial installations; if included, production can be run while monitoring plasma reaction and deposition reaction.

By disposing a pair of conductive flat-plate electrodes, an upper electrode 2 and a lower electrode 4 parallel to and facing each other inside a reactor 1 and applying RF power 8 of, for example, 13.56 MHz to one side of the electrodes and grounding the other side of the electrodes, plasma is excited between a pair of the electrodes. The lower electrode 4 functions as a lower stage supporting a substrate as well, and the substrate 3 is placed on the lower stage 4. A temperature-regulating mechanism is attached to the lower stage 4; during the deposition, a temperature is kept at a given temperature, for example, about 0° C. to about 450° C. (preferably about 150° C. to about 400° C.) (This is the same for a substrate temperature.). A source gas, for example, Dimethyldimetoxysilane (DM-DMOS, Si (CH₃)₂(OCH₃)₂) and an inert gas, for example, Ar are mixed and used as a reaction gas. These gases are controlled at respective given flow rates through a flow controller 9, are mixed, and introduced into an inlet port 12 disposed at the top of the upper electrode (shower plate) 2 as a reaction gas.

Method of Measuring a Size and Density of a Nanoparticle

By applying a coagulation/dispersion method, a size and density of a nanoparticle can be measured. One example of discharge conditions and laser-beam incoming conditions is described below, but the conditions are not limited to this example.

Incoming Ar Ion Laser Condition:

Incoming power: Up to 1 W
Laser diameter: 5 mm (when an ICCD camera is used); 0.5 mm (when PMT is used)

Laser beam from Ar+laser (488 nm, 1 W) 14 is irradiated, reflected by a mirror 13; with its direction of polarization being uniformed by goring through a Glan-Thompson Prism 11, the laser beam is irradiated by a mirror 10 into the reactor 1 through a vacuum insulating glass (made of quartz, etc.) window 5 provided on a wall of the reactor 1. The laser beam passing through a nanoparticle generation region inside the reactor 1 and through a window 6 provided on a facing wall is observed by an ICCD camera 7 (or photodetected by an electronic photomultiplier (PMT)). By observing a thermal coagulation phenomenon between particles using a laser dispersion method, a fine particle size can be readily-measured.

Nanoparticle Size Control and Discharge Period

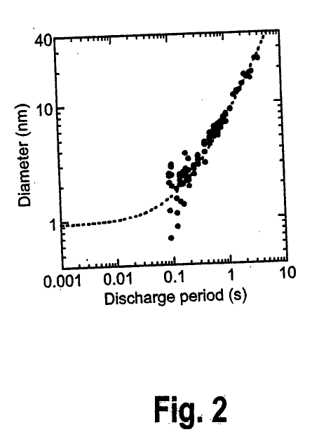

Nanoparticle sizes can be determined by controlling a discharge period. In FIG. 2, an example of the dependency of a discharge period on a nanoparticle size is shown. This experiment was conducted under the conditions of RF power of 13.56 MHz at 11.9 W/cm², a discharge period of 0.3 sec., 4000 sccm of Ar, 20 sccm of DMDMOS, a pressure of 1 Torr, a substrate temperature at 250° C., an electrode size of +200 mm, an electrode interval of 20 mm, a gas flow velocity within a discharge region (a direction parallel to an electrode surface) of 1.0 cm/sec., and by observing a thermal coagulation phenomenon between particles using a laser dispersion method, a fine particle size was readily-measured. As seen from this figure, in this example, in 0.1 sec. after discharge is started, nanoparticles having a diameter of about 1 nm are generated and their size becomes larger as the discharge period elapses. It is seen that a discharge period of about 0.15 sec. is required for growing a nanoparticle size linearly to the discharge period and producing nanoparticles having a diameter of about 2 nm.

By selecting the discharge period, particle sizes can be controlled within the range of about 1 nm to about 30 nm. Additionally, the reason why sizes vary widely in the vicinity of 1 nm is that a size and signal strength readily-measured suddenly decrease in the vicinity of 1 nm, thereby worsening an S/N ratio. When a size is decreased to ½, readily-measured signal strength is decreased up to (½)⁶. This is a measurement problem. By TEM observation, it was confirmed that size control was able to be executed with precision even in a small size region.

A dotted line is a linear approximated curve of experimental data, from which about 6.5 nm/sec. is obtained as a size-growth rate. When the data was fitted, 0.93 nm was used as an initial molecular size of DMDMOS. It is seen that a size of nanoparticles can be controlled at a nanometer order size linearly and accurately by controlling a discharge period within the range of about 1 msec to about 1 sec. As just described, a particle generation phenomenon by plasma CVD of nonconductor Si insulator particles has not been reported.

Transport Time of Generated Nanoparticles to a Substrate

Nanoparticles are transported by diffusion and by gas stream; and generally two different effects are intermixed. An apparatus configuration and a pressure are determined based on which effect is preferred for main transport means. When a pressure is low and an electrode interval is narrow, transport of nanoparticles by diffusion becomes dominant; when a pressure is high, nanoparticles are transported by a gas stream, which is faster than a diffusion velocity.

A transport phenomenon by diffusion is that nanoparticles generated in the vicinity of RF electrodes are transported to a substrate while being diffused via collision with gas molecules. A diffusion coefficient D (a spread area of particles per unit time) prescribing a diffusion velocity is obtained by the following formula:

$$D = {\frac{3}{2 {{N}_{g} ( {n}^{1 / 3} {d}_{Si} + {d}_{g} )}^{2}} [ \frac{{k}_{B} {T}_{g} ( {nm}_{Si} + {m}_{g} )}{2 π {nm}_{Si} {m}_{g}} ]}^{1 / 2}$$

where N_{g}, T_{g,} d_{g} and mg are gas density, gas temperature, and a diameter and mass of a gas molecule respectively; d_{Si}, m_{Si} and n are a diameter, mass of a silicon atom and the number of atoms comprising a fine particle; k_{B} is Boltzmann constant. Additionally, although this diffusion coefficient is of silicon atoms dispersing between inert gas molecules, it can be applied to an Si-containing gas whose Si content is high. Additionally, even if the content of other atoms becomes high, fundamentals applied are the same.

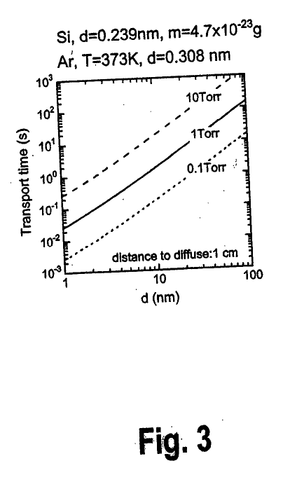

The transport time is defined as τ_{d}=L²/D, where L is a transport distance (electrode interval). Although the transport time depends on a fine particle size and a gas pressure, it is generally about 0.1 sec. to about 1 sec. for a fine particle of several nanometers under the conditions of a gas pressure of 1 Torr, mass of about 10⁻²³ kg, Ar used as an inert gas, and a gas temperature of 100° C. In FIG. 3, the transport time required for the transport when a transport distance by diffusion is set at 1 cm is shown (other conditions are the same as those applied to the experiments of the nanoparticle size control and the discharge period.). The transport time becomes shorter, as the finer particles under a low gas pressure are, the more easily the fine particles diffuse. Additionally, the transport time range is not much affected by a type of source gas, a type of inert gas, a gas temperature, etc.

When an electrode interval L is 20 mm, the transport time by diffusion is about 0.4 sec.; when L is 10 mm, the transport time by diffusion is about 0.1 sec. When this transport time elapses, particle density between the electrodes is sufficiently reduced; if RF power is turned on after the transport time has elapsed, generation of nanoparticles begins again. By repeating these steps consecutively, a film thickness deposited can be increased.

When fine particles are transported mainly by gas stream, by expanding a formula below,

$$N \times A = \frac{{τ}_{d} \times Q}{L \times P}$$

Q: Gas flow rate (sccm)
τ_{d}: Transport time (sec.)
N: Number of gas nozzles of the shower plate
A: Cross section area of gas nozzle of the showerhead (cm²)
P: Pressure inside the reactor (Torr)
L: Electrode interval inside the reactor (cm)
the transport time Td can be described by the following formula obtained:

$${τ}_{d} = \frac{P \times L \times N \times A}{Q} .$$

By increasing a gas flow rate, the transport time can be shortened, and it is possible to transport nanoparticles at a transport speed significantly higher than the above-mentioned transport speed by diffusion.

Suppressing Coagulation Growth of Fine Particles During Transport

In order to produce fine and uniform porous films, suppressing coagulation growth of fine particles during transport becomes extremely important. If fine particles coagulate in the middle of transport, ‘floc’ is formed, and producing fine uniform porous films becomes difficult. The coagulation growth time arising from thermal motions between the fine particles is obtained by: τ_{c}=1/k_{c}nₚ; where k_{c} and nₚ are a coagulation coefficient and density of fine particles respectively, and a coagulation coefficient is obtained by the following formula:

$${k}_{c} = {( \frac{9 π {k}_{B} {T}_{p} {d}_{p}}{ρ} )}^{1 / 2}$$

Tₚ, dₚ and ρ are a temperature, diameter and mass density of fine particles respectively. Additionally, a gas molecular factor is not included in the calculation of a coagulation coefficient; because a distance between nanoparticles is in micron order under the nanoparticles' density condition being 10¹¹ cm⁻³ whereas the effective mean free path of nanoparticles is in 0.1 mm order under the gas pressure condition of about 1 Torr, effects of suppressing coagulation by gas molecules can be ignored. In other words, coagulation of nanoparticles progresses along with the time elapsing independently of transport of nanoparticles.

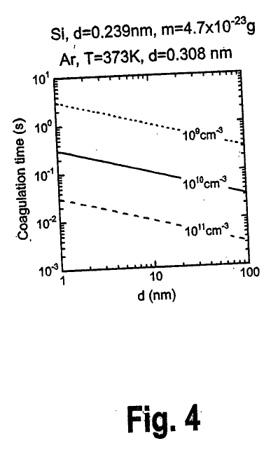

In FIG. 4, coagulation time of fine particles is shown. (Other conditions are the same as those applied to the experiments of the nanoparticle size control and the discharge period.). For nanoparticles with the fine particle density of 10¹⁰ cm⁻³, the coagulation time (τ_{c}) is about 0.1 sec. to about 0.3 sec. In order to suppress coagulation growth of fine particles during transport, it is preferable to shorten the transport time than the coagulation time (τ_{d}<τ_{c}). In other words, it is preferable to suppress an amount of fine particles generated to some extent and to shorten a transport distance.
τ_{d}<τ_{c}

Although the transport time is determined by two effects, diffusion and gas stream effects, it is preferable to increase the transport speed by gas stream in order to satisfy the above-mentioned relational expression because τ_{d} only by transport by diffusion is generally large (from 0.1 sec to 1 sec. in the above-mentioned example). In the case of the transport system in which transport by gas stream is dominant to the extent that transport by diffusion can be ignored, coagulation during transport can be controlled by a gas stream condition. When L=1 cm, A=0.0079 cm² (φ 0.5 mm), N=9000 with the coagulation growth time τ_{c}=0.1 sec., a gas flow rate to be introduced to the reactor is calculated using the following formula:

$$Q > \frac{P \times L \times N \times A}{{τ}_{c}}$$

Coagulation during transport can be suppressed by forming a film under the condition of:
Q>237 sccm.

With the above-mentioned conditions, it is preferable that Q>300 sccm, 500 sccm, 1000 sccm, 2000 sccm, 3000 sccm, 4000 sccm, 5000 sccm, 6000 sccm, and values between the foregoing. However, as described before, a gas flow rate (in a direction parallel to an electrode surface) is preferably 2.5 cm/sec. or below, and an appropriate gas stream is selected based on the relation with a reactor size, etc.

Film Properties

A dielectric constant of a film obtained by the above-mentioned method is 2.0-2.5 according to one embodiment; further 2.1-2.4. Additionally, a modulus of a film formed is about 1 GPa to about 4 GPa according one embodiment (a modulus is improved by about 10% to about 50% after the cure step). Additionally, RI is 1.1-1.3 according to one embodiment; furthermore, porosity is about 30% to about 85%; further about 40% to about 75%, or about 50% to about 70%. Additionally, although a film thickness can be adjusted appropriately and is not particularly limited, in one embodiment, it is about 20 nm to about 2000 nm in one embodiment; further about 50 nm to about 1000 nm, or about 100 nm to about 500 nm.

Film Formation Example

Using a capacitively-coupled CVD apparatus (having basic configurations similar to Eagle-10™ (ASM Japan)) and under the conditions described below, an SiOH-containing low-k film with a film thickness of 400 nm was formed on a substrate having a thickness of 0.8 mm by repeating a cycle of generating and depositing nanoparticles at a give temperature gradient between a showerhead (powered or upper electrode) and a susceptor (substrate or lower electrode).
Susceptor temperature: 100° C., 115° C., 145° C., 200° C., or 250° C.
Showerhead temperature: 95° C.
Distance between the susceptor and the showerhead: 10 mm
Electrode size: φ60 mm
Gas common conditions: Ar 40 sccm, DMDMOS 0.2 sccm,
   Gas flow rate inside a discharge area (parallel to an electrode surface) 1.0 cm/sec. 1 Torr,
RF Power 13.56 MHz, 75 W (11.9 W/cm²)
RF ON time: 0.15 sec., OFF time: 0.5 sec.
Deposition time: 470 sec.

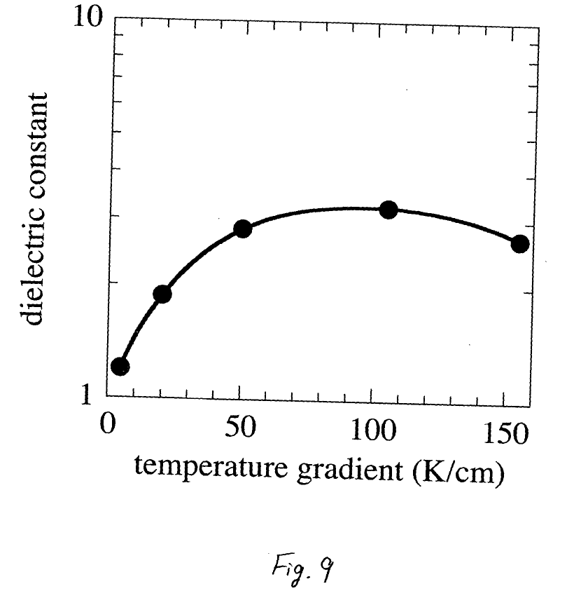

Properties of a film obtained were as follows:
Thickness: 1,400 nm
Film density (g/cm³): See FIG. 8
Dielectric constant: See FIG. 9

SiOCH nanoparticles was produced using RF discharges of DMDMOS (dimethyldimethoxysilane) diluted with the other gases. Their size and density were measured by an in situ laser light scattering method (M. Shiratani and Y. Watanabe, Rev. Laser Eng. 26, 449 (1998)) and ex situ transmission electron microscopy. The measurements show the production of size-controlled nanoparticles having 1-20 nm in diameter, small dispersion, and 10¹² to 10⁹ cm⁻³ in number density.

The nanoparticles and radicals were then co-deposited on a substrate as a parameter of the gas temperature gradient between the substrate and the upper electrode. Results are shown in FIG. 8. The film density increased sharply from 0.2 to 1.8 g/cm³ as the temperature gradient increased from 5 to 50 K/cm, since the nanoparticle flux decreased significantly. Above 50 K/cm, the density becomes nearly constant as the nanoparticle flux to the substrate was marginal in such temperature gradient range. The dielectric constant of the films was in a range of 1.3-2.7 as shown in FIG. 9. The FTIR analysis of the films reveals that the films were constituted by Si—O, Si—CH₃, Si—O—C, but nearly no Si—H. These results indicate that the film density and dielectric constant were easily controlled. In FIGS. 8 and 9, the temperature gradient was calculated based on the distance and the temperature difference between the upper electrode and the susceptor. However, in the above, through experiments, it was assumed that the substrate temperature was substantially similar to that of the susceptor. The distance between the substrate and the upper electrode was 9.2 mm. Thus, the temperature gradient between the substrate and the upper electrode can be calculated at 1.087 times that shown in FIGS. 8 and 9.

As described above, according to at least one embodiment of the present invention, it becomes possible to form low-k films by plasma CVD. Using these low-k films as insulating films for highly-integrated semiconductor devices, it becomes possible to substantially lower operation speeds of semiconductor devices by lowering delays caused by interconnect capacitance.

The present invention is not limited to the following embodiments, but includes the following:

1) Films are formed using a capacitively-coupled CVD apparatus under the following conditions:
An organo Si gas (expressed by a general formula Si_{α}H_{β}O_{γ}C_{λ}: α, β, γ, λ are arbitrary integers.), which contains at least Si, and comprising C, O and H in addition to Si, is used as a source gas.
A flow rate ratio of the organo Si gas is diluted with an inert gas to 10% or below.
A reaction pressure is set in a pressure scope of 0.1-10 Torr.
By generating fine particles with a nanometer order size in the vapor phase and by depositing these particles onto a substrate, low-k insulating films are formed.

2) The organo silicon gas is expressed by a general formula Si_{α}O_{α-1}R_{2α-β+2}(OCₙH₂ₙ₊₁)_{β}, wherein α is an integer of 1-3, β is 0, 1, 2, 3 or 4, n is an integer of 1-3, and R is C₁₋₆ hydrocarbon attached to Si.

3) The organo silicon gas is SiR_{4-α}(OCₙH₂ₙ₊₁)_{β}, wherein α is 0, 1, 2, 3 or 4, n is an integer of 1-3, and R is C₁₋₆ hydrocarbon attached to Si.

4) The organo silicon gas is Si₂OR_{6-α}(OCₙH₂ₙ₊₁)_{α}, wherein α is 0, 1, 2, 3 or 4, n is an integer of 1-3, and R is C₁₋₆ hydrocarbon attached to Si.

5) The organo silicon gas is SiH_{β}R_{4-α}(OCₙH₂ₙ₊₁)_{α-β}, wherein α is 0, 1, 2, 3 or 4, β is 0, 1, 2, 3 or 4, n is 1 or 2, and R is C₁₋₆ hydrocarbon attached to Si.

6) By forming nanoparticles by applying RF power for 1 msec to 1 sec and by combining a deposition process in which applying RF power is turned off during the particle transport time, a film is deposited. Continuous operation once or multiple times is included.

7) An organo Si gas, DMDMOS, Si(CH₃)₂(OCH₃)₂, as a source gas and Ar as an inert gas are used.

8) As RF power, RF power of 13.56 MHz, 27 MHz or 60 MHz is used.

9) VHF power of 100 MHz or above is used.

10) When VHF power is used, a spoke antenna electrode is used.

11) A film is formed at a substrate temperature within the range of 0-450° C.

12) A film is formed at a substrate temperature in the range of 150-400° C.

13) As an organo Si gas, one or a combination of multiple gases selected from the group consisting of Si(CH₃)₄, Si(CH₃)₃(OCH₃), Si(CH₃)₂(OCH₃)₂, Si(CH₃)(OCH₃)₃, Si(OCH₃)₃, Si(CH₃)₃(OC₂H₅), Si(CH₃)₂(OC₂H₅)₂, Si(CH₃)(OC₂H₅)₃, Si(OC₂H₅)₄, SiH(CH₃)₃, SiH₂(CH₃)₂, SiH₃(CH₃) is used.

14) As an inert gas, Ar or one of multiple gases selected from the group consisting of He, Ne, Kr, Xe and N₂ or a combination thereof is used.

15) By adding an oxidizing gas such as O₂, CO, CO₂ and N₂O, a carbon concentration of a thin film formed is adjusted.

16) A film is formed under the condition of shortening the nanoparticle transport time in a reaction space.

17) In order to improve mechanical strength of a film, a film formed is cured by thermal treatment combining with UV or EB.

18) In order to improve mechanical strength of a film, a film formed is cured by thermal treatment combining with plasma processing, UV or EB.

19) An electronic RF matching box is used.

20) After a fine-particle film is formed, by performing the steps of letting the film stand in organo silicon gas atmosphere, adhering organo silicon molecules to the fine particle film and curing the film, mechanical strength of the film is improved.

21) After a fine-particle film is formed, by repeating the steps of letting the film stand in H₂O gas atmosphere and letting the film stand in organo silicon gas atmosphere once or multiple times, mechanical strength of the film is improved.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A method for forming low dielectric constant films comprising the steps of:
introducing reaction gas comprising an organo Si gas and an inert gas into a reactor of a capacitively-coupled CVD apparatus;
adjusting a size of nanoparticles being generated in the vapor phase to a nanometer order size as a function of a plasma discharge period inside the reactor; and
depositing nanoparticles generated on a substrate being placed between upper and lower electrodes inside the reactor while controlling a temperature gradient between the substrate and the upper electrode at about 100° C./cm or less.

2. The method according to claim 1, wherein the temperature gradient is controlled at about 50° C./cm or less.

3. The method according to claim 1, wherein the temperature gradient is controlled to satisfy −10≦(Ts−Tp)/L≦50, wherein Ts is a temperature of the substrate (° C.), Tp is a temperature of the upper electrode (° C.), and L is a distance between the substrate and the upper electrode (cm).

4. The method according to claim 1, wherein in the depositing step, the upper electrode is controlled at a temperature of about 50° C. to about 250° C.

5. The method according to claim 1, wherein the upper and lower electrodes are set apart at a distance of about 5 mm to about 30 mm.

6. The method according to claim 1, wherein a film being formed by the deposited nanoparticles has a dielectric constant of 1.3-2.7.

7. The method according to claim 6, wherein the dielectric constant of the film being formed is controlled as a function of the temperature gradient between the substrate and the upper electrode.

8. The method according to claim 7, wherein the dielectric constant of the film being formed is reduced by reducing the temperature of the substrate.

9. The method according to claim 1, wherein a flow rate of the organo Si gas is 10% or below as against a flow rate of the inert gas.

10. The method according to claim 1, wherein the plasma discharge is executed by applying RF power at about 8 W/cm² to about 13 W/cm².

11. The method according to claim 1, wherein fine particles are formed with a single round of plasma discharge period set at about 1 msec. to about 1 sec.

12. The method according to claim 1, wherein plasma discharge is stopped during a period when fine particles are deposited on the substrate.

13. The method according to claim 1, wherein plasma discharge is executed intermittently.

14. The method according to claim 13, wherein one cycle is composed of the steps of forming fine particles by setting a single round of plasma discharge period at about 10 msec. to about 1 sec. and stopping plasma discharge after the single round of plasma discharge for about 100 msec. to about 2 sec. while depositing the fine particles generated on the substrate, and at least two cycles or more are executed.

15. The method according to claim 14, wherein in a configuration in which the reaction gas is introduced through a gas nozzle of a shower plate provided inside the reactor, plasma discharge is executed between upper and lower electrodes, and a substrate is placed on the lower electrode, a flow rate of reaction gas is adjusted to satisfy the following relational expression:
$$\frac{P \times L \times N \times A}{Q} < 0.1$$
Q: Gas flow rate (sccm)
N: Number of gas nozzles of the shower plate
A: Cross sectional area of a gas nozzle of the shower plate (cm²)
P: Pressure inside the reactor (Torr)
L: Electrode interval (cm)

16. The method according to claim 1, wherein a flow velocity of the reaction gas, which is parallel to the substrate surface, is adjusted so as to be 2.5 cm/sec. inside the reactor.

17. The method according to claim 1, wherein a pressure inside the reactor during plasma discharge is about 0.1 Torr to about 10 Torr.

18. The method according to claim 1, wherein the plasma discharge is conducted using RF power of 13.56 MHz, 27 MHz, 60 MHz.

19. The method according to claim 1, wherein the organo Si gas is one or more compounds expressed by Si_{α}O_{α-1}R_{2α-β+2}(OCₙH₂ₙ₊₁)_{β} wherein α is an integer of 1-3, P is 0, 1, 2, 3 or 4, n is an integer of 1-3, and R is C₁₋₆ hydrocarbon attached to Si, SiR_{4-α}(OCₙH₂ₙ₊₁)_{α} wherein α is 0, 1, 2, 3 or 4, n is an integer of 1-3, and R is C₁₋₆ hydrocarbon attached to Si, Si₂OR_{6-α}(OCₙH₂ₙ₊₁)_{α} wherein α is 0, 1, 2, 3 or 4, n is an integer of 1-3, and R is C₁₋₆ hydrocarbon attached to Si, or SiH_{β}R_{4-α}(OCₙH₂ₙ₊₁)_{α-β} wherein α is 0, 1, 2, 3 or 4, β, is 0, 1, 2, 3 or 4, n is 1 or 2, and R is C₁₋₆ hydrocarbon attached to Si.

20. The method according to claim 1, wherein the reaction gas further comprises an oxidizing gas containing at least one of O₂, CO, CO₂ or N₂O for adjusting carbon concentration of a film formed.

21. The method according to claim 1, further comprising, after film formation, the step of curing a film formed by thermal treatment by any one or a combination of plasma processing, UV or EB, thereby improving mechanical strength of the film.

22. The method according to claim 1, further comprising, after film formation, the steps of adhering organo silicon molecules to the film by letting the substrate stand in organo silicon gas atmosphere, and curing the film, thereby improving mechanical strength of the film.

23. The method according to claim 1, further comprising, after film formation, the step of repeating a process of letting the film stand in H₂O gas atmosphere and letting the film stand in organo silicon gas atmosphere once or multiple times, thereby improving mechanical strength of the film.

24. A method for forming a low dielectric constant film, comprising the steps of:
introducing reaction gas comprising an organo Si gas and an inert gas into a reactor of a capacitively-coupled CVD apparatus;
adjusting a flow rate of reaction gas so as to satisfy a relational expression below
$$\frac{P \times L \times N \times A}{Q} < 0.1$$
Q: Gas flow rate (sccm)
N: Number of gas nozzles of the shower plate
A: Cross sectional area of a gas nozzle of the shower plate (cm²)
P: Pressure inside the reactor (Torr)
L: Electrode interval (cm);
adjusting a size of fine particles being generated from the organo Si gas in the vapor phase to a size of about 10 nm or below as a function of a plasma discharge period in the reactor; and
depositing the fine particles generated on a substrate being placed between upper and lower electrodes inside the reactor by stopping plasma discharge while controlling a temperature gradient between the substrate and the upper electrode at about 100° C./cm or less.

25. The method according to claim 24, wherein the temperature gradient is controlled to satisfy −10≦(Ts−Tp)/L≦50, wherein Ts is a temperature of the substrate (° C.), Tp is a temperature of the upper electrode (° C.), and L is a distance between the substrate and the upper electrode (cm).

26. The method according to claim 1, wherein a film being formed by the deposited nanoparticles has a dielectric constant of 1.3-2.7.

27. The method according to claim 24, wherein one cycle is composed of the steps of forming fine particles by setting a single round of plasma discharge period at about 10 msec. to about 1 sec. and depositing the fine particles generated on the substrate by stopping plasma discharge after the single round of plasma discharge for about 100 msec. to about 2 sec., and at least two cycles or more is executed.

28. The method according to claim 25, wherein a low dielectric constant film is formed by consecutively repeating the cycle 30 to 150 times.

29. The method according to claim 24, wherein porosity of the film generated is about 40% to about 80%.

30. A method for forming a low dielectric constant film comprising the steps of:
(A) introducing reaction gas comprising an organo Si gas and an inert gas into a reactor;
(B) forming fine particles from the organo Si gas by executing plasma discharge for about 100 msec. to about 2 sec.; and
(C) depositing the fine particles onto a substrate being placed between upper and lower electrodes inside the reactor while controlling a temperature gradient between the substrate and the upper electrode at about 100° C./cm or less.

31. The method according to claim 30, wherein the temperature gradient is controlled to satisfy −10≦(Ts−Tp)/L≦50, wherein Ts is a temperature of the substrate (° C.), Tp is a temperature of the upper electrode (° C.), and L is a distance between the substrate and the upper electrode (cm).

32. The method according to claim 1, wherein a film being formed by the deposited nanoparticles has a dielectric constant of 1.3-2.7.

33. The method according to claim 30, wherein an average size of the fine particles is about 1 nm to about 10 nm.

34. A method for forming a low dielectric constant film comprising the steps of:
(A) introducing reaction gas comprising an organo Si gas and an inert gas into a reactor and executing plasma discharge for forming nanoparticles from the organo Si gas; and
(B) depositing nanoparticles on a substrate placed between upper and lower electrodes in the reactor by controlling the time required for forming nanoparticles from the organo Si gas (T1), while controlling a temperature gradient between the substrate and the upper electrode at about 100° C./cm or less, the time required for transporting nanoparticles formed to the substrate being placed inside the reactor (T2), and the time until coagulation growth takes place between nanoparticles during transport (T3) as functions of a plasma discharge period and a gas flow rate.

35. The method according to claim 34, wherein in step (B), T1, T2 and T3 are controlled to become nearly T1=0.1-1 sec. and T2<T3.

36. The method according to claim 34, wherein in step (B), T1, T2 and T3 are controlled to become nearly T1=0.1-1 sec., T1=T2 and T3=0.

37. The method according to claim 34, wherein the temperature gradient is controlled to satisfy −10≦(Ts−Tp)/L≦50, wherein Ts is a temperature of the substrate (° C.), Tp is a temperature of the upper electrode (° C.), and L is a distance between the substrate and the upper electrode (cm).

38. A method for forming a low dielectric constant film comprising the steps of:
(A) introducing reaction gas comprising an organo Si gas and an inert gas into a reactor and executing plasma discharge for forming nanoparticles from the organo Si gas; and
(B) controlling deposition of nanoparticles onto a substrate placed between upper and lower electrodes in the reactor using the time required for forming nanoparticles from the organo Si gas (T1), the time required for transporting nanoparticles formed to the substrate being placed inside the reactor (T2), and the time until coagulation growth takes place between nanoparticles during transport (T3) as control parameters, while controlling a temperature gradient between the substrate and the upper electrode at about 100° C./cm or less.

39. The method according to claim 38, wherein in step (B), T1, T2 and T3 are controlled to become nearly T1=0.1-1 sec., and T2<T3.

40. The method according to claim 38, wherein in step (B), T1, T2 and T3 are controlled to become nearly T1=0.1-1 sec., T1=T2, and T3=0.

41. The method according to claim 38, wherein the temperature gradient is controlled to satisfy −10≦(Ts−Tp)/L≦50, wherein Ts is a temperature of the substrate (° C.), Tp is a temperature of the upper electrode (° C.), and L is a distance between the substrate and the upper electrode (cm).
